(19) United States
(12) Patent Application Publication
(10) Pub. No.: US 2022/0157622 A1
(43) Pub. Date: May 19, 2022

(54) CHIP PACKAGING METHOD AND CHIP PACKAGE UNIT

(71) Applicant: Richtek Technology Corporation, Zhubei City (TW)

(72) Inventors: Heng-Chi Huang, Hsinchu (TW); Yong-Zhong Hu, Cupertino, CA (US); Hao-Lin Yen, Taoyuan (TW)

(21) Appl. No.: 17/485,339

(22) Filed: Sep. 25, 2021

Related U.S. Application Data
(60) Provisional application No. 63/113,233, filed on Nov. 13, 2020.

(30) Foreign Application Priority Data
Mar. 10, 2021 (TW) 110108482

(51) Int. Cl. H01L 21/48; H01L 21/683; H01L 21/78; H01L 23/373

(52) U.S. Cl. CPC H01L 21/4875; H01L 21/6836; H01L 21/78; H01L 2221/68386; H01L 23/3733; H01L 2221/68327; H01L 23/3736

(57) ABSTRACT

A chip packaging method includes: providing plural chip units; providing a base material, and placing the chip units on the base material; providing an adhesive layer to adhere a metal foil to the chip unit, wherein the metal foil is a part of the base material or additional to the base material; and cutting the chip units on the base material to form plural separated chip package units, wherein each of the chip package units includes a cut metal foil part.

### CROSS REFERENCE

The present invention claims priority to provisional application 63/113,233 filed on Nov. 13, 2020, and TW 110108482 filed on Mar. 10, 2021.

### BACKGROUND OF THE INVENTION

### Field of Invention

The present invention relates to a chip packaging method, and particularly to a chip packaging method in which, during the packaging process, when cutting the chip units the metal foil adhered to the chip units is simultaneously cut.

### Description of Related Art

FIG. 1 shows a chip package unit according to U.S. Pat. No. 6,023,096. A substrate 110 under the chip CH is provided with an opening. A metal foil 120 is provided under the opening. A package material 100 is filled under the chip CH, in the space between the opening of the substrate 110 and the metal foil 120. The metal foil 120 helps to enhance heat dissipation from the chip CH, but the related manufacturing process is very complicated. Complicated steps include: that openings need to be made in the substrate 110; that the metal foil 120 is disposed on the package material 100 when the package material 100 is not fully hardened; that the process of adhering the metal foil 120 requires etching, positioning, heating, and pressing, etc.

FIG. 2 shows a chip package unit according to U.S. Pat. No. 6,411,507, in which a metal cover 130 having a complicated shape is required for thermal contact with the chip CH. The complicated shape of the metal cover 130 requires a complicated manufacturing process. Further, how to correctly place the metal cover 130 to achieve the best thermal contact performance with the chip CH is another technical challenge. In addition, due to restriction in manufacture technique, the metal cover 130 has a minimum size limit, so this prior art is not suitable for packaging small-size chip units.

Please refer to FIG. 3, wherein the chip package unit of U.S. Pat. No. 8,794,889 is shown. In order to improve the heat dissipation from the chip CH, a heat dissipation fin structure 140 is disposed on the chip CH. When mounting the heat dissipation fin structure 140, a thermal paste is required to be applied onto the chip CH, so that heat in a gap between the chip CH and the heat dissipation fin structure 140 can be dissipated. In addition, the heat dissipation fin structure 140 is fastened to the chip CH by screws SC, which requires additional work by a user, and if the user is not familiar with the fastening process or forgets to apply the thermal paste, the heat dissipation performance will be degraded. In short, this design is nor user-friendly. Besides, the heat dissipation fin structure 140 also has its minimum size limit, such that it is not suitable for packaging small-size chip units.

In view of the above, to overcome the drawbacks in the prior art, the present invention proposes a chip package unit, which has the benefits of simple and easy manufacturing process, low cost, and no size limitation, and a corresponding chip packaging method.

### SUMMARY OF THE INVENTION

From one perspective, the present invention provides a chip packaging method to overcome the aforementioned problems. This chip packaging method includes: providing a plurality of chip units, or a wafer including a plurality of chip units; providing a base material, and placing the chip units or the wafer on the base material; providing an adhesive layer to adhere a metal foil to the chip unit or to the wafer, wherein the metal foil is a part of the base material or additional to the base material; and cutting the chip units on the base material or cutting the chip units in the wafer, to form a plurality of separated chip package units, wherein each of the chip package units includes a cut metal foil part.

In one embodiment, the aforementioned adhesive layer includes an adhesive material with high heat transfer capability. The cut metal foil part is adhered to the chip unit by and through the adhesive layer. The heat generated during the operation of the chip unit can be transferred to the metal foil via the adhesive layer, and then further transferred to the outside of the chip package unit.

In one embodiment, plural chip units are adhered to the adhesive layer, and a package material is provided to encapsulate the plural chip units.

In one embodiment, the surface area of the cut metal foil part is substantially equal to the top area of the chip package unit. During operation of the chip unit, the cut metal foil part can improve the heat dissipation from the chip unit by increasing the heat dissipation area on the chip unit, which can greatly reduce the heat concentration, to achieve a better heat distribution for rapid heat transfer. The cut metal foil part and the adhesive layer form a high-efficiency heat transfer side of the chip package unit.

In one embodiment, the base material includes a wafer dicing tape. After cutting the wafer on the wafer dicing tape into a plurality of chip package units, each chip package unit can be peeled from the wafer dicing tape. In each chip package unit, the cut metal foil part is still adhered to the chip unit by the adhesive layer.

In one embodiment, the material of the metal foil includes copper, aluminum, silver, nickel, or a composite metal alloy material having a heat transfer coefficient higher than that of the package material. In one embodiment, the surface of the metal foil is coated with a graphene layer, to further increase the heat transfer coefficient of the metal foil.

In another aspect, the present invention provides a chip package unit, which includes: a chip unit; an adhesive layer and a metal foil, the metal foil adhered to the chip unit by the adhesive layer, wherein the metal foil and the adhesive layer form a high-efficiency heat transfer side of the chip package unit; and a base material and a package material, wherein the chip unit is disposed on the base material, and the package material encapsulates lateral sides of the chip unit.

The objectives, technical details, features, and effects of the present invention will be better understood with regard to the detailed description of the embodiments below, with reference to the attached drawings.

### BRIEF DESCRIPTION OF THE DRAWINGS

FIGS. 1, 2, and 3 show chip package units of prior arts.

FIGS. 4A to 4F and 5A to 5E show steps of the chip packaging method according to two embodiments of the present invention.

FIGS. 6 to 12 show schematic diagrams of chip package units according to several embodiments of the present invention.

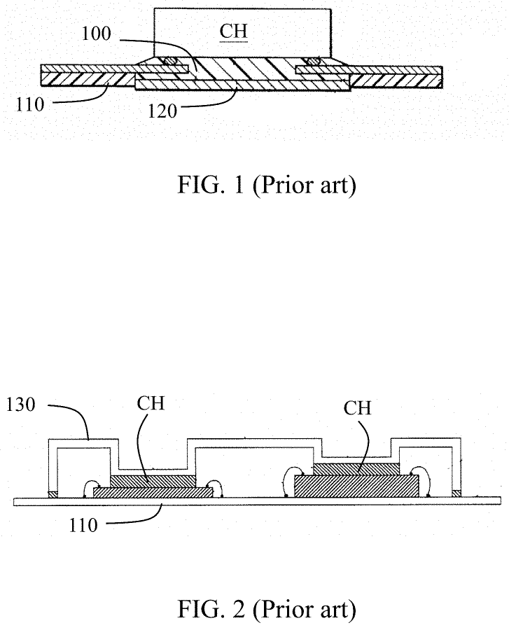

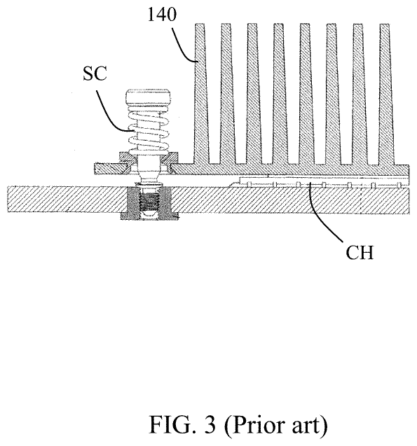

### DESCRIPTION OF THE PREFERRED EMBODIMENTS

The drawings as referred to throughout the description of the present invention are for illustration only, to show the interrelations between the components of the circuit, but not drawn according to actual scale of circuit sizes.

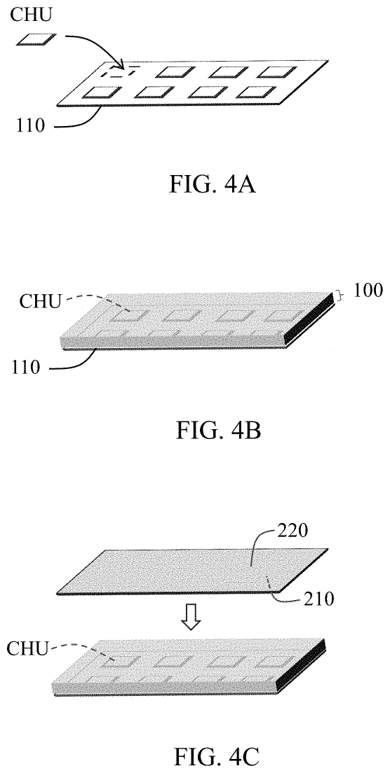

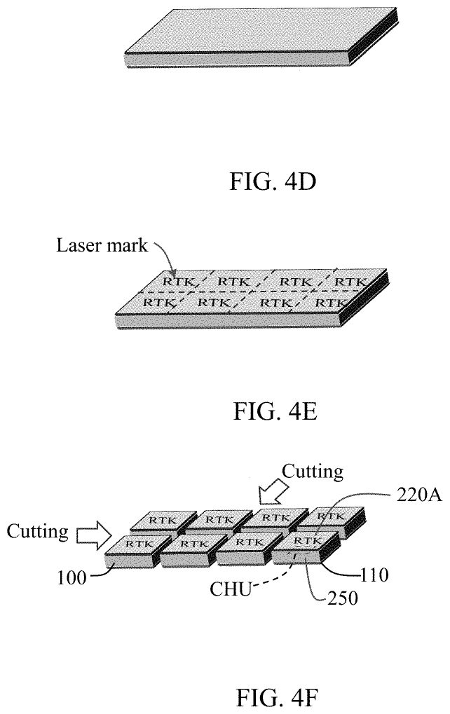

FIGS. 4A to 4F show steps of the chip packaging method according to one embodiment of the present invention. The chip packaging method primarily includes: providing plural chip units CHU (FIG. 4A); providing a base material 110, and placing the chip units CHU on the base material 110 (FIG. 4B); providing an adhesive layer 210 and a metal foil 220, wherein the adhesive layer 210 is for adhering the metal foil 220 on the chip unit CHU (FIG. 4C, wherein the metal foil 220 is on top and the adhesive layer 210 is below the metal foil 220); and after the adhesion is completed (FIG. 4D), cutting the chip units CHU on the base material 110 (FIGS. 4E and 4F), to form plural separated chip package units 250 (FIG. 4F), wherein each chip package unit 250 includes a part of the metal foil 220 (referred to as cut metal foil part 220A). Note that the chip units CHU shown in FIGS. 4B and 4C include a package material 100, which is optional and the details will be explained in later description of other embodiments.

FIGS. 4E and 4F show laser marks on the chip package units 250 before and after cutting the chip package units 250. Laser marks are known technology, so its details are not redundantly explained here.

In the foregoing step of placing the chip units CHU on the base material 110, the plural chip units CHU can be separately arranged on the base material 110 (FIG. 4A), i.e., with proper spacing in between.

In one embodiment, the adhesive layer 210 includes an adhesive material with high heat transfer capability to provide good thermal contact efficiency between the metal foil 220 and the chip unit CHU (or wafer WF). The cut metal foil part 220A is adhered to the chip unit CHU by the adhesive layer 210. The heat generated by the operation of the chip unit CHU can be transferred to the cut metal foil part 220A via the adhesive layer 210, and is further transferred to the outside of the chip package unit 250.

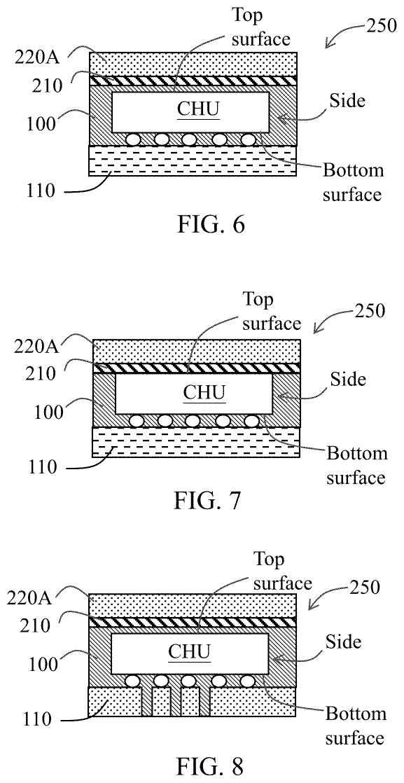

In one embodiment, the base material (such as a substrate stripe or a lead frame stripe) on which plural chip units CHU are disposed, is not required to include the adhesion layer 210 and the metal foil 220. The chip units CHU can be disposed on the base material 110, and the adhesive layer 210 and the metal foil 220 can be disposed on the other side of the plurality of chip units CHU. The chip package units 250 made by this arrangement are shown in FIGS. 6, 7, 8, 9, 10, and 11.

In one embodiment, the plural chip units CHU are adhered to the adhesive layer 210 (FIG. 4A), and the package material 100 is provided to encapsulate the plural chip units CHU (FIG. 4B).

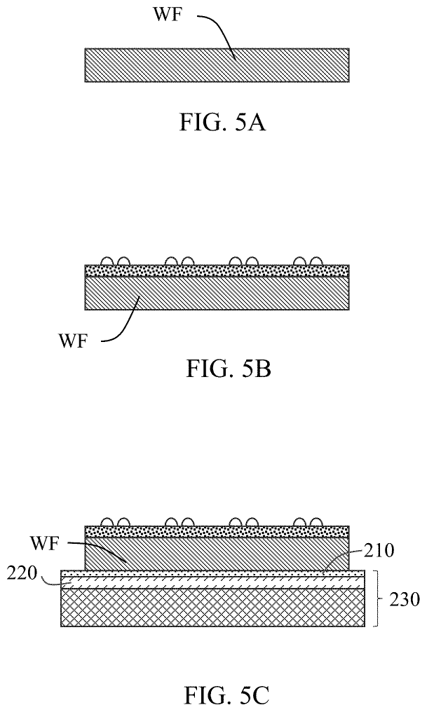

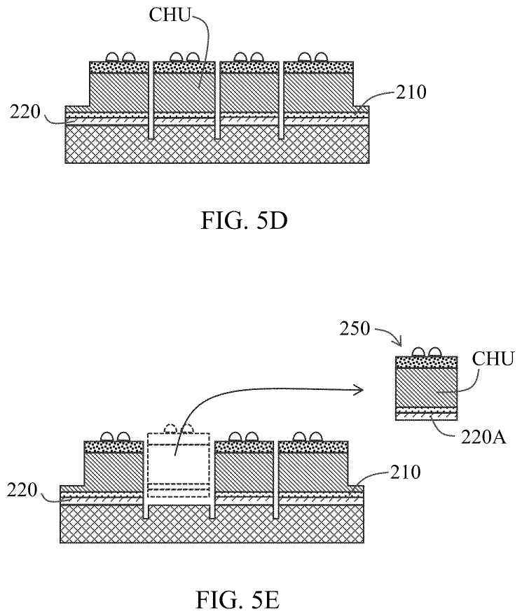

FIGS. 5A to 5E show steps of a chip packaging method according to one embodiment of the present invention. The chip packaging method includes: providing a wafer WF including plural chip units (FIG. 5A); providing a base material 230 (FIG. 5C) and disposing the wafer WF on the base material 230, and adhering a metal foil 220 to the wafer WF (FIG. 5C) by an adhesive layer 210, wherein the metal foil 220 and the adhesive layer 210 can be regarded as a part of the base material 230 (as the reference number 230 illustrates), or, regarded as separated components form the base material 230 (in this case the reference number 230 should only refer to the lowest layer in FIG. 5C); and cutting the chip units in the wafer WF (FIG. 5D) to form plural separated chip package units 250 (FIG. 5E), wherein each chip package unit 250 includes a cut metal foil part 220A.

In one embodiment, in the aforementioned step of providing the wafer WF (FIGS. 5A and 5B) including plural chip units CHU, the plural chip units can be in an uncut form (i.e. connected with one another as one piece) in the wafer WF, and after cutting the chip units in the wafer WF, the chip units then become separated chip units.

In one embodiment of the method, the adhesive layer 210 includes an adhesive material with high heat transfer efficiency and good thermal contact capability between the metal foil 220 and the chip unit CHU (or between the metal foil 220 and the wafer WF). The cut metal foil part 220A is adhered to the chip unit CHU by the adhesive layer 210. The heat generated in the operation of the chip unit CHU can be transferred to the cut metal foil part 220A via the adhesive layer 210, and is further transferred to the outside of the chip package unit 250.

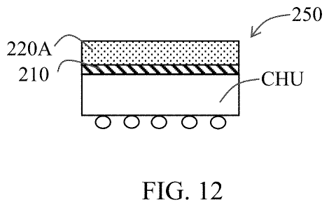

In one embodiment, referring to FIG. 5C, the base material 230 on which the wafer WF is disposed is for example a wafer dicing tape, which include a metal foil 220 and an adhesive layer 210, and the metal foil 220 is adhered to the wafer WF by an adhesive layer 210. The chip package units 250 are removed by peeling them from the wafer dicing tape. The chip package unit 250 is for example as shown in FIG. 12. In each of the chip package units 250, the adhesive layer 210 still adheres the cut metal foil part 220A to the chip unit CHU. In another embodiment, the base material on which plural chip units CHU are disposed is for example a substrate stripe or a lead frame stripe, which does not include the adhesion layer 210 and the metal foil 220. The chip units CHU are disposed on the base material 110, while the adhesive layer 210 and the metal foil 220 are disposed on the other side of the chip units CHU. The chip package unit 250 according to this arrangement for example are as shown in FIGS. 6, 7, 8, 9, 10, and 11.

Please refer to the chip package unit 250 shown in FIGS. 6, 7, 8, 9, 10, and 11, wherein the package material 100 encapsulates the lateral sides of each chip unit CHU, and optionally, also encapsulates the bottom surface of the chip unit CHU facing the base material 110 (FIGS. 6, 7, 8, 9, 10, and 11), and optionally, also encapsulates the top surface on the side opposite to the bottom surface (FIGS. 6, 8, 10, and 11). In one embodiment, the package material 110 encapsulates the lateral sides (or lateral sides and bottom surfaces) of the chip units CHU, and the cut metal foil part 220A is adhered to the top surface of the chip units CHU by the adhesive layer 210. In one embodiment, the package material 110 encapsulates the top surfaces and sides (or top surfaces, sides and bottom surfaces) of the chip units CHU, and the cut metal foil parts 220A are adhered to the top surfaces of the chip units CHU by the adhesive layer 210.

Compared with the prior art, in the packaging process of the present invention, the metal foil 220 is not disposed on a side of the base material 110 opposite to the side facing the chip unit CHU. Therefore, when cutting the chip package unit 250, the metal foil 220 is cut simultaneously, which can avoid many complicated processes in the prior art such as the requirement of creating an opening in base material 110 for accommodating the metal foil 220, etc. Thus, the present invention has advantages of simpler process, easier manufacture, and lower cost.

In one embodiment, after disposing the adhesive layer 210 and the metal foil 220 on the chip units CHU, a baking process is performed to cure the adhesive layer 210, to strengthen the bonding between the metal foil 220 and the chip unit CHU.

In one embodiment, the surface area of the cut metal foil part 220A is equal to the top area of the chip package unit 250. (The term “equal” does not require “exactly equal”; a certain amount of tolerable error is acceptable.) When operating the chip unit CHU, the cut metal foil part 220A can improve the heat dissipation efficiency for the chip unit CHU by increasing the heat dissipation area of the chip unit CHU, which greatly releases heat concentration to achieve good heat dispersion. The cut metal foil part 220A and the adhesive layer 210 provide a high-efficiency heat transfer side of the chip package unit 250.

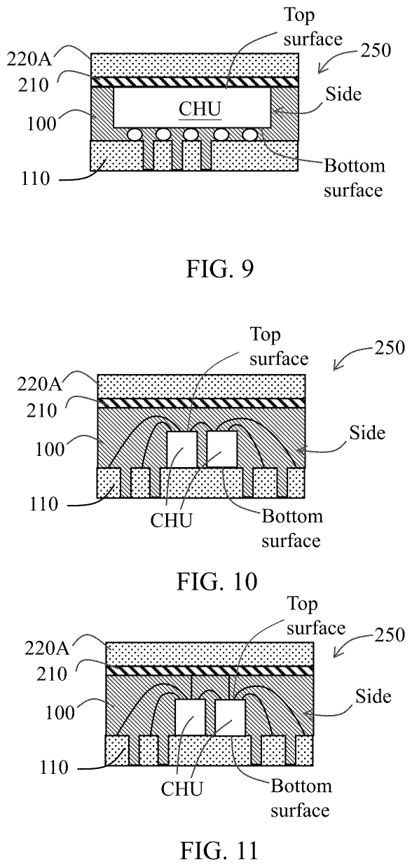

In one embodiment, the base material includes a substrate strip or a lead frame strip (for example, the base material 110 is a substrate strip in FIGS. 6 and 7, and the base material 110 is a lead frame strip in FIGS. 9, 10, and 11). The chip unit CHU can be mounted on the base material 110 by flip chip (FIGS. 6, 7, 8, and 9) or wire bond (FIGS. 10, 11), as the application requires.

In the embodiment wherein the wafer WF is placed on a wafer dicing tape, before placing the wafer WF on the wafer dicing tape, a redistribution layer can be formed on the wafer WF, to connect the nodes in the circuits of the chip units CHU to different layout locations by wirings in the redistribution layer, to match for chip package requirement.

In one embodiment, the material of the metal foil 220 includes copper, aluminum, silver, nickel, or a composite metal alloy material, having a heat transfer coefficient higher than that of the package material. Due to packaging requirement for the chip unit, it is the first priority of the package materials to have good packaging molding or overmolding capability, and therefore the heat transfer capability of the selected package material is usually just ordinary, which is insufficient to meet good heat dissipation requirement. The metal foil 220 can greatly improve the heat dissipation efficiency to satisfy this requirement. In one embodiment, the surface of the metal foil 220 is coated with a graphene layer, which can further improve the heat transfer efficiency of the chip unit CHU via the metal foil 220.

Please refer to FIGS. 7 to 12, in one perspective, the present invention provides a chip package unit 250, which includes: a chip unit CHU; and an adhesive layer 210 and a cut metal foil part 220A, wherein the cut metal foil part 220A is adhered to the chip unit CHU by the adhesive layer 210. The cut metal foil part 220A and the adhesive layer 210 form a high-efficiency heat transfer side of the chip package unit 250. The chip package unit 250 may optionally include a base material 110 (substrate or lead frame) and a package material 100, and the chip unit CHU is placed on the base material 110. The package material 100 encapsulates the lateral sides of the chip unit CHU, and optionally encapsulates a bottom surface of the chip unit CHU facing the base material 110 or a top surface (on the opposite side to the bottom surface) of the chip unit CHU.

For the detail of each part in the chip package unit, please refer to the description of the previously described embodiments, which are not redundantly repeated here.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equal tos.

What is claimed is:

1. A chip packaging method, including:
providing a plurality of chip units, or a wafer including a plurality of chip units;
providing a base material, and placing the chip units or the wafer on the base material;
providing an adhesive layer to adhere a metal foil to the chip unit or to the wafer, wherein the metal foil is a part of the base material or additional to the base material; and
cutting the chip units on the base material or cutting the chip units in the wafer, to form a plurality of separated chip package units, wherein each of the chip package units includes a cut metal foil part.

2. The chip packaging method according to claim 1, wherein the chip units are adhered to the metal foil by the adhesive layer, and a package material is provided to encapsulate the chip units, wherein the package material encapsulates lateral sides of each of the chip units.

3. The chip packaging method according to claim 2, wherein the package material further encapsulates a bottom surface of each of the chip units facing the base material, and/or further encapsulates a top surface on an opposite side of each of the chip units to the bottom surface.

4. The chip packaging method according to claim 2, wherein in each of the chip package units, the cut metal foil part is adhered to a top surface of the chip unit by the adhesive layer.

5. The chip packaging method according to claim 3, wherein the package material encapsulates the top surface of each of the chip units, and in each of the chip package units, the cut metal foil part is adhered to the package material on the top surface.

6. The chip packaging method according to claim 1, wherein the metal foil is not disposed on a side of the base material opposite to another side of the base material facing the chip units.

7. The chip packaging method according to claim 1, wherein a surface area of the cut metal foil part is equal to a top area of the chip package unit, wherein the cut metal foil part and the adhesive layer form a high-efficiency heat transfer side of the chip package unit.

8. The chip packaging method according to claim 1, wherein the base material includes: a substrate stripe, a lead frame stripe, or a wafer dicing tape.

9. The chip packaging method according to claim 8, wherein when the base material includes a substrate strip or a lead frame strip, the chip units are mounted on the base material by flip chip or wire bond.

10. The chip packaging method according to claim 8, wherein when the base material is the wafer dicing tape, each of the chip package units is peeled off from the wafer dicing tape after cutting the wafer on the wafer dicing tape, wherein in each of the chip package units, the cut metal foil part is adhered to the corresponding chip unit by the adhesive layer.

11. The chip packaging method according to claim 8, wherein before the wafer is disposed on the wafer dicing tape, a redistribution layer is formed on the wafer.

12. The chip packaging method according to claim 1, wherein the material of the metal foil includes copper, aluminum, silver, nickel, or a composite metal alloy material.

13. The chip packaging method according to claim 1, wherein the surface of the metal foil is coated with a graphene layer.

14. A chip package unit, including:
a chip unit;
an adhesive layer and a metal foil, the metal foil adhered to the chip unit by the adhesive layer, wherein the metal foil and the adhesive layer form a high-efficiency heat transfer side of the chip package unit; and
a base material and a package material, wherein the chip unit is disposed on the base material, and the package material encapsulates lateral sides of the chip unit.

15. The chip package unit according to claim 14, wherein the package material further encapsulates a bottom surface of the chip unit facing the base material, and/or further encapsulates a top surface on the opposite side of the chip unit to the bottom surface.

16. The chip package unit according to claim 14, wherein a surface area of the metal foil is equal to a top area of the chip package unit.
